(19) United States
(12) Patent Application Publication
(10) Pub. No.: US 2016/0197235 A1
(43) Pub. Date: Jul. 7, 2016

(54) LIGHT-EMITTING ELEMENT

(71) Applicant: LG INNOTEK CO., LTD., Seoul (KR)

(72) Inventors: Youn Joon SUNG, Seoul (KR); Sung Hoon JUNG, Seoul (KR); Jun Ho SUNG, Seoul (KR); Hee Jin JO, Seoul (KR)

(73) Assignee: LG INNOTEK CO., LTD., Seoul (KR)

(21) Appl. No.: 14/915,757

(22) PCT Filed: Aug. 12, 2014
(86) PCT No.: PCT/KR2014/007475

§ 371 Date: Mar. 1, 2016

(30) Foreign Application Priority Data
Sep. 2, 2013 (KR) 10-2013-0104707
Jul. 18, 2014 (KR) 10-2014-0090793

(51) Int. Cl. H01L 33/20; H01L 33/32

(52) U.S. Cl. CPC H01L 33/20; H01L 33/32

(57) ABSTRACT

Disclosed is a light-emitting element according to an embodiment, comprising: a light-emitting structure comprising a first conductivity-type semiconductor layer, an active layer, and a second conductivity-type semiconductor layer; and a light extractor arranged on the light-emitting structure, the light extractor comprising: a first nitride semiconductor layer with a first wet etch rate, arranged on the first conductivity-type semiconductor layer, a second nitride semiconductor layer with a second wet etch rate, arranged on the first nitride semiconductor layer, and a third nitride semiconductor layer with a third wet etch rate, wherein the first and third wet etch rates are lower than the second wet etch rate.

### TECHNICAL FIELD

Embodiments relate to a light emitting device.

### BACKGROUND ART

Group III-V nitride semiconductors such as GaN are in the spotlight as essential materials for semiconductor optical devices such as light emitting diodes (LEDs), laser diodes (LDs) and solar cells owing to excellent physical and chemical properties.

Group III-V nitride semiconductor optical devices come into spotlight as elements of light emitting devices since they have blue and green light bands, and exhibit high brightness and excellent reliability.

Light efficiency of light emitting devices may be determined by internal quantum efficiency and light extraction efficiency (also called “external quantum efficiency”).

Nitride semiconductor layers constituting light emitting devices have high refractive indexes, as compared to external air, or sealing materials or substrates, thus decreasing a critical angle that determines a range of an incidence angle at which light can be emitted. For this reason, a great amount of light generated by the active layer is total reflected into the nitride semiconductor layers, resulting in light loss and decreased light extraction efficiency.

### DISCLOSURE

### Technical Problem

Embodiments provide a light emitting device capable of uniformly improving light extraction efficiency.

### Technical Solution

In one embodiment, a light emitting device includes a light emitting structure including a first conductivity-type semiconductor layer, an active layer and a second conductivity-type semiconductor layer, and a light extraction portion disposed on the light emitting structure, wherein the light extraction portion includes a first nitride semiconductor layer being disposed on the first conductivity-type semiconductor layer and having a first wet etch rate, and a second nitride semiconductor layer being disposed on the first nitride semiconductor layer and having a second wet etch rate, and a third nitride semiconductor layer having a third wet etch rate, wherein the first wet etch rate and the third wet etch rate are lower than the second wet etch rate.

The light extraction portion may further include a first uneven structure including a protrusion and a recess, the protrusion having a structure in which the second nitride semiconductor layer and the third nitride semiconductor layer are stacked, and a second uneven structure formed on the third nitride semiconductor layer of the first uneven structure.

Each of the first nitride semiconductor layer and the third nitride semiconductor layer may have a composition including aluminum and the second nitride semiconductor layer may have a composition excluding aluminum.

Each of the first to third nitride semiconductor layers may have a composition including aluminum and an aluminum content of each of the first nitride semiconductor layer and the third nitride semiconductor layer may be greater than an aluminum content of the second nitride semiconductor layer.

The composition of the first nitride semiconductor layer may be AlₓGa₍₁₋ₓ₎N (0<x≦1), the composition of the third nitride semiconductor layer may be Al_{y}Ga_{(1-y)}N (0<y≦1), and the composition of the second nitride semiconductor layer may be AlₓGa_{(1-z)}N (0≦z≦1), in which x and y are greater than z.

The first uneven structure may have a regular pattern shape and the second uneven structure may have an irregular pattern shape.

The recess of the first uneven structure may expose an upper surface of the first nitride semiconductor layer.

The light extraction portion may further include a third uneven structure formed on the upper surface of the first nitride semiconductor layer exposed by the recess of the first uneven structure.

Each of the first nitride semiconductor layer and the third nitride semiconductor layer may have a thickness of 5 nm to 50 nm.

A ratio of the first wet etch rate to the second wet etch rate, and a ratio of the third wet etch rate to the second wet etch rate may be 1:5 to 1:100.

The light emitting device may further include a first electrode disposed on the light extraction portion and a second electrode disposed under the second conductivity-type semiconductor layer.

In another embodiment, a light emitting device includes a light emitting structure including a first conductivity-type semiconductor layer, an active layer and a second conductivity-type semiconductor layer, and a light extraction portion disposed on the light emitting structure, wherein the light extraction portion includes a first nitride semiconductor layer disposed on the light emitting structure, a first uneven structure including a protrusion and a recess, the protrusion including a second nitride semiconductor layer disposed on the first nitride semiconductor layer and a third nitride semiconductor layer disposed on the first nitride semiconductor layer, and a second uneven structure formed on a surface of the third nitride semiconductor layer of the first uneven structure, wherein the first nitride semiconductor layer has a first wet etch rate, the second nitride semiconductor layer has a second wet etch rate, the third nitride semiconductor layer has a third wet etch rate, and the first wet etch rate and the third wet etch rate are lower than the second wet etch rate.

Each of the first nitride semiconductor layer and the third nitride semiconductor layer may have a composition including aluminum and the second nitride semiconductor layer may have a composition excluding aluminum.

Each of the first to third nitride semiconductor layers may have a composition including aluminum and an aluminum content of each of the first nitride semiconductor layer and the third nitride semiconductor layer may be greater than an aluminum content of the second nitride semiconductor layer.

The composition of the first nitride semiconductor layer may be AlₓGa₍₁₋ₓ₎N (0<x≦1), the composition of the third nitride semiconductor layer may be Al_{y}Ga_{(1-y)}N (0<y≦1), and the composition of the second nitride semiconductor layer may be Al_{z}Ga_{(1-z)}N (0≦z≦1), in which x and y are greater than z.

The first uneven structure may have a regular pattern shape and the second uneven structure may have an irregular pattern shape.

The recess of the first uneven structure may expose an upper surface of the first nitride semiconductor layer.

The light extraction portion may further include a third uneven structure formed on the upper surface of the first nitride semiconductor layer exposed by the recess of the first uneven structure.

The light extraction portion may further include a fourth uneven structure formed on a side surface of the protrusion.

Each of the first nitride semiconductor layer and the third nitride semiconductor layer may have a thickness of 5 nm to 50 nm.

A ratio of the first wet etch rate to the second wet etch rate, and a ratio of the third wet etch rate to the second wet etch rate may be 1:5 to 1:100.

The light emitting device may further include a first electrode disposed on the light extraction portion and a second electrode disposed under the second conductivity-type semiconductor layer.

### Advantageous Effects

Embodiments provide a light emitting device capable of uniformly improving light extraction efficiency.

### DESCRIPTION OF DRAWINGS

FIG. 1 illustrates a sectional view of a light emitting device according to an embodiment.

FIGS. 2 to 8 illustrate a method for fabricating a light emitting device according to an embodiment.

FIG. 9 illustrates an enlarged view of a groove formed by dry etching of FIG. 5.

FIG. 10 illustrates a first embodiment of a light extraction portion shown in FIG. 1.

FIG. 11 illustrates a second embodiment of the light extraction portion shown in FIG. 1.

FIG. 12 illustrates a third embodiment of the light extraction portion shown in FIG. 1.

FIG. 13 illustrates a fourth embodiment of the light extraction portion shown in FIG. 1.

FIG. 14 illustrates a fifth embodiment of the light extraction portion shown in FIG. 1.

FIG. 15 illustrates a sixth embodiment of the light extraction portion shown in FIG. 1.

FIGS. 16A to 16E illustrate embodiments of a protrusion of a first uneven structure included in the light extraction portion.

FIGS. 17A to 16C illustrate other embodiments of the protrusion of the first uneven structure shown in FIG. 10.

FIGS. 17D to 16F illustrate other embodiments of the protrusion of the first uneven structure shown in FIG. 14.

FIG. 18 shows simulation results of light extraction efficiency of the light emitting device according to height of the protrusion shown in FIG. 10.

FIG. 19 shows simulation results of light extraction efficiency of the light emitting device according to height of a protrusion having a hemispherical or oval hemispherical shape.

FIG. 20 shows simulation results of light extraction efficiency of the light emitting device according to height of a protrusion having a truncated cone shape.

FIG. 21 illustrates a light emitting device package according to another embodiment.

FIG. 22 illustrates a lighting device including the light emitting device according to another embodiment.

FIG. 23 illustrates a display device including the light emitting device according to another embodiment.

### BEST MODE

Hereinafter, embodiments will be clearly understood from the annexed drawings and the description associated with the embodiments. In description of the embodiments, it will be understood that when an element, such as a layer (film), a region, a pattern or a structure, is referred to as being “on” or “under” another element, such as a layer (film), a region, a pad or a pattern, the term “on” or “under” means that the element is directly on or under the other element or intervening elements may also be present. It will also be understood that “on” or “under” is determined based on the drawings.

In the drawings, the sizes of elements may be exaggerated, omitted or schematically illustrated for convenience in description and clarify. Further, the sizes of elements do not mean the actual sizes of the elements. Wherever possible, the same reference numbers will be used throughout the drawings to refer to the same parts. Hereinafter, the light emitting device according to embodiments will be described with reference to the annexed drawings.

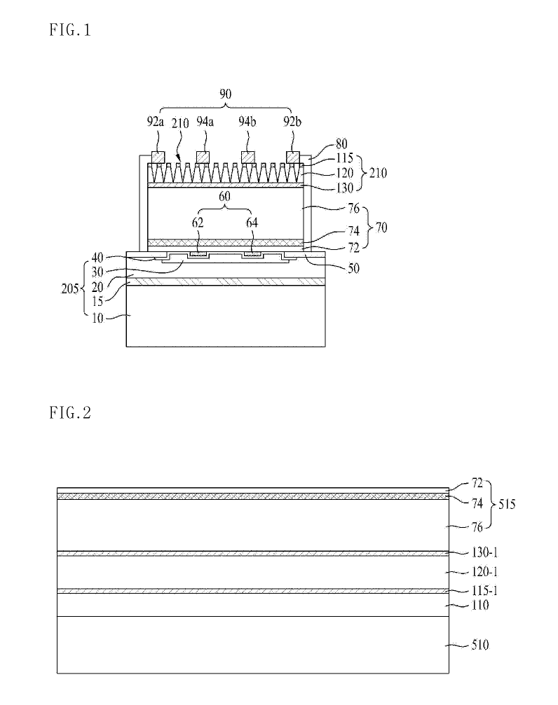

FIG. 1 illustrates a sectional view of a light emitting device 100 according to an embodiment.

Referring to FIG. 1, the light emitting device 100 includes a second electrode 205, a protective layer 50, a current blocking layer 60, a light emitting structure 70, a passivation layer 80, a first electrode 90, and a light extraction portion 210.

The second electrode 205 supports the light emitting structure 70 and supplies power to light emitting structure 70 together with the first electrode 90.

The second electrode 205 may include a support substrate 10, an adhesive layer 15, a diffusion preventing layer 20, a reflective layer 30, and an ohmic layer 40.

The support substrate 10 may support the light emitting structure 70. The support substrate 10 may be a conductive material, for example, a metal including at least one of copper (Cu), gold (Au), nickel (Ni), molybdenum (Mo), and copper-tungsten (Cu—W), or a semiconductor including at least one of Si, Ge, GaAs, ZnO, and SiC.

The adhesive layer 15 may be disposed between the support substrate 10 and the diffusion preventing layer 20, and may function to adhere the support substrate 10 to the diffusion preventing layer 20. In a case where the diffusion preventing layer 20 is omitted, the adhesive layer 15 may be disposed between the support substrate 10 and the reflective layer 30. Alternatively, in a case where the diffusion preventing layer 20 and the reflective layer 30 are omitted, the adhesive layer 15 may be disposed between the support substrate 10 and the ohmic layer 40.

For example, the adhesive layer 15 may include an adhesive metal, for example, a metal or alloy including at least one of Au, Sn, Ni, Nb, In, Cu, Ag and Pd.

The adhesive layer 15 is formed to adhere the support substrate 10 by bonding and may be omitted when the support substrate 10 is formed by plating or deposition.

The diffusion preventing layer 20 may be disposed between the support substrate 10 and the reflective layer 30, and between the support substrate 10 and the protective layer 50, and may prevent metal ions of the adhesive layer 15 and the support substrate 10 from passing through the reflective layer 30 and the ohmic layer 40, and diffusing into the light emitting structure 70. For example, the diffusion preventing layer 20 may include a barrier material, for example, at least one of Ni, Pt, Ti, W, V, Fe, and Mo and may be a single layer or a multi-layer.

The reflective layer 30 may be disposed on the diffusion preventing layer 20 and may reflect light incident from the light emitting structure 70 to improve light extraction efficiency. The reflective layer 30 may be formed of a light-reflecting material, for example, a metal or an alloy including at least one of Ag, Ni, Al, Rh, Pd, Ir, Ru, Mg, Zn, Pt, Au, and Hf.

The reflective layer 30 may be formed as a multilayer, for example, IZO/Ni, AZO/Ag, IZO/Ag/Ni, or AZO/Ag/Ni using a metal or alloy, and a light-transmitting conductive material.

The ohmic layer 40 may be disposed between the reflective layer 30 and a second conductivity-type semiconductor layer 72, and ohmic-contact the second conductivity-type semiconductor layer 72 to facilitate supply of power to the light emitting structure 70. The ohmic layer 40 may be formed by selectively using a light-transmitting conductive layer and a metal.

For example, the ohmic layer 40 may include a metal material ohmic-contacting the second conductivity-type semiconductor layer 72 and the metal material may for example include at least one of Ag, Ni, Cr, Ti, Pd, Ir, Sn, Ru, Pt, Au, and Hf.

The protective layer 50 may be disposed at an edge of the second electrode 205.

As shown in FIG. 1, the protective layer 50 is disposed at an edge of the diffusion preventing layer 30, but not limited thereto. In another embodiment, the protective layer 50 may be disposed at an edge of the ohmic layer 40, or at an edge of the reflective layer 30, or at an edge of the support substrate 10.

The protective layer 50 may prevent deterioration in reliability of the light emitting device 100 caused by detachment of the interface between the light emitting structure 70 and the second electrode 205. The protective layer 50 may be formed of a non-conductive material, for example, ZnO, SiO₂, Si₃N₄, TiOₓ (in which x is a positive real number), or Al₂O₃.

The current blocking layer 60 may be disposed between the ohmic layer 40 and the light emitting structure 70, and may disperse current present within the light emitting structure 70, thereby improving optical efficacy.

An upper surface of the current blocking layer 60 may contact the second conductivity-type semiconductor layer 72, and a lower surface, or the lower surface and a side surface of the current blocking layer 60 may contact the ohmic layer 40.

The current blocking layer 60 may be disposed such that at least a part thereof overlaps the first electrode 90 in a vertical direction. For example, current blocking layers 62 and 64 may be disposed such that they partially overlap first electrodes 94a and 94b in a vertical direction. The vertical direction may be a direction from the second conductivity-type semiconductor layer 72 to a first conductivity-type semiconductor layer 76.

The current blocking layer 60 may be formed between the ohmic layer 40 and the second conductivity-type semiconductor layer 72, or between the reflective layer 30 and the ohmic layer 40.

The light emitting structure 70 may be disposed on the ohmic layer 40 and the protective layer 50. A side surface of the light emitting structure 70 may be an inclined surface in an isolation etching process (see FIG. 7) for separation into unit chips.

The light emitting structure 70 may include the second conductivity-type semiconductor layer 72, an active layer 74, and the first conductivity-type semiconductor layer 76.

The second conductivity-type semiconductor layer 72, the active layer 74, the first conductivity-type semiconductor layer 76, and the light extraction portion 210 may be sequentially stacked on the second electrode 205.

The second conductivity-type semiconductor layer 72 may be disposed on the ohmic layer 40 and the protective layer 50, may be formed of a semiconductor compound such as a Group III-V or II-VI semiconductor compound, or may be doped with a second conductivity-type dopant.

The second conductivity-type semiconductor layer 72 may be formed of a semiconductor having a composition of InₓAl_{y}Ga_{1-x-y}N (0≦x≦1, 0≦y≦1, 0≦x+y≦1). For example, the second conductivity-type semiconductor layer 72 may include any one of InAlGaN, GaN, AlGaN, InGaN, AlN and InN, and be doped with a p-type dopant (for example, Mg, Zn, Ca, Sr, or Ba).

The active layer 124 may be disposed on the second conductivity-type semiconductor layer 72 and generate light by energy created during recombination of electrons and holes supplied from the first conductivity-type semiconductor layer 76 and the second conductivity-type semiconductor layer 72.

The active layer 74 may be formed of a semiconductor compound, for example, a Group III-V or II-VI compound semiconductor, and have a single well structure, a multi-well structure, a quantum wire structure, a quantum dot structure or a quantum disk structure.

The active layer 74 may have a composition of InₓAl_{y}Ga_{1-x-y}N (0≦x≦1, 0≦x+y≦1). If the active layer 74 has a quantum well structure, the active layer 74 may include a well layer (not shown) having a composition of InₓAl_{y}Ga_{1-x-y}N 0≦x≦1, 0≦x+y≦1) and a barrier layer (not shown) having a composition of InₐAl_{b}Ga_{1-a-b}N (0≦a+b≦1).

The energy bandgap of the well layer may be less than the energy bandgap of the barrier layer. The well layer and the barrier layer may be alternately stacked at least one time.

Energy bandgaps of the well layer and the barrier layer may be constant in respective ranges, but not limited thereto. For example, a composition of indium (In) and/or aluminum (Al) of the well layer may be constant, and a composition of indium (In) and/or aluminum (Al) of the barrier layer may be constant.

Alternatively, the energy bandgap of the well layer may include at least one gradually increasing or decreasing region and the energy bandgap of the barrier layer may include at least one gradually increasing or decreasing region. For example, a composition of indium (In) and/or aluminum (Al) of the well layer may gradually increase or decrease, and a composition of indium (In) and/or aluminum (Al) of the barrier layer may gradually increase or decrease.

The first conductivity-type semiconductor layer 76 may be disposed on the active layer 74, may be formed of a compound semiconductor, i.e., a Group III-V or II-VI compound semiconductor, and be doped with a first conductivity-type dopant.

The first conductivity-type semiconductor layer 76 may be formed of a semiconductor having a composition of InₓAl_{y}Ga_{1-x-y}N (0≦x≦1, 0≦y≦1, 0≦x+y≦1). For example, the first conductivity-type semiconductor layer 76 may include a nitride semiconductor containing aluminum, for example, any one of InAlGaN, AlGaN, and AlN, and be doped with an n-type dopant (for example, Si, Ge, Se or Te).

A conductive clad layer may be disposed between the active layer 74 and the first conductivity-type layer 76, or between the active layer 74 and the second conductivity-type semiconductor layer 72. The conductive clad layer may be formed of a nitride semiconductor (for example, AlGaN, GaN or InAlGaN).

The light emitting structure 70 may further include a third conductivity-type semiconductor layer (not shown) between the second conductivity-type semiconductor layer 72 and the second electrode 205. The third conductivity-type semiconductor layer may have polarity opposite to the polarity of the second conductivity-type semiconductor layer 72. Further, in another embodiment, the first conductivity-type semiconductor layer 76 may be implemented by a p-type semiconductor layer and the second conductivity-type semiconductor layer 72 may be implemented by an n-type semiconductor layer. Accordingly, the light emitting structure 70 may include at least one of an N-P junction structure, a P-N junction structure, an N-P-N junction structure and a P-N-P junction structure.

The light extraction portion 210 may be disposed on the light emitting structure 70 to improve light extraction efficiency and may be provided with a first nitride semiconductor layer 130, a second nitride semiconductor layer 120, and a third nitride semiconductor layer 115.

The light extraction portion 210 may include an uneven structure including at least one recess and at least one protrusion. The uneven structure included in the light extraction portion 210 may have a frustum-of-pyramid, truncated cone, conical, hemispherical or oval hemispherical shape, but not limited thereto.

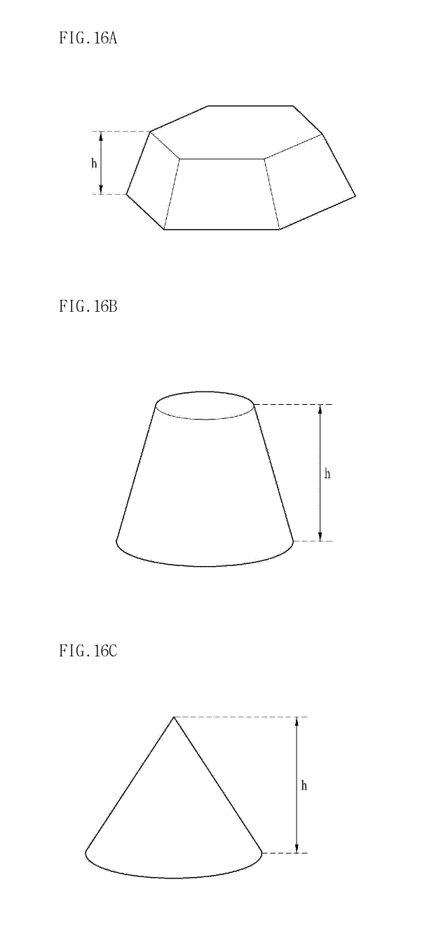

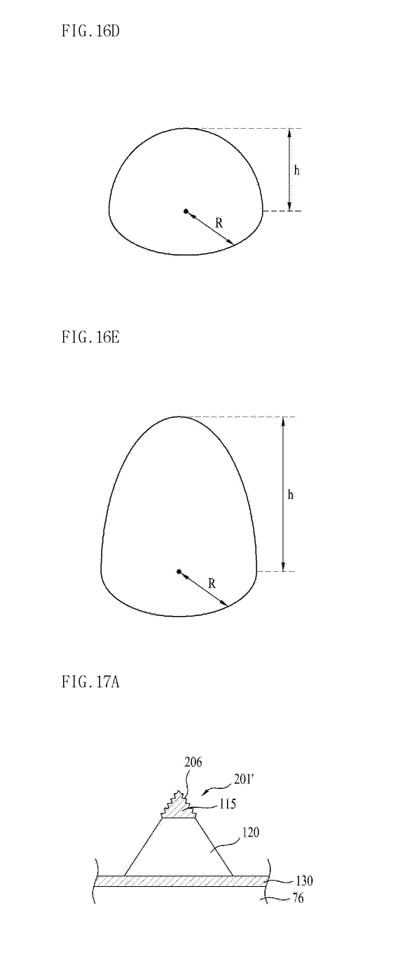

FIGS. 16A to 16E illustrate embodiments of a protrusion of a first uneven structure included in the light extraction portion 210. The light extraction portion 210 may have a frustum-of-pyramid (for example, frustum-of-hexagonal pyramid), truncated cone, conical, hemispherical or oval hemispherical shape, as shown in FIG. 16A, 16B, 16C, 16D, or 16E, respectively.

FIG. 10 illustrates a first embodiment of the light extraction portion 210 shown in FIG. 1.

Referring to FIG. 10, the light extraction portion 210 may include the first nitride semiconductor layer 130, a first uneven structure 203, and a second uneven structure 206.

The first nitride semiconductor layer 130 may be disposed on the first conductivity-type semiconductor layer 76.

The first uneven structure 203 may include the second nitride semiconductor layer 120 and the third nitride semiconductor layer 115 sequentially staked on the first nitride semiconductor layer 130.

The first uneven structure 203 may have a regular pattern shape, but not limited thereto.

For example, the first uneven structure 203 may have a protrusion 201 and a recess 202, and the protrusion 201 may have a structure in which the second nitride semiconductor layer 120 and the third nitride semiconductor layer 115 are stacked.

The shape of the protrusion 201 of the first uneven structure 203 may be any one of frustum-of-pyramid, truncated cone, conical, hemispherical and oval hemispherical shapes shown in FIGS. 16A to 16E, but not limited thereto.

For example, the shape of the protrusion 201 of the first uneven structure 203 shown in FIG. 10 may be any one of a frustum-of-pyramid and a truncated cone, but not limited thereto.

For example, the protrusion 201 of the first uneven structure 203 may include an upper surface and a side surface, wherein the shape of the upper surface may be a polygon (for example, a rectangle or hexagon), and the side surface include a plurality of surfaces in which the respective surfaces may be in the form of polygon. The side surface may be an inclined surface that inclines based on the upper surface, and an angle between the side surface and the upper surface may be a right angle or an obtuse angle, but not limited thereto.

The recess 202 may be surrounded by the protrusion 201 and may have a groove structure. For example, the recess 202 may be in the form of a pinhole exposing the first nitride semiconductor layer 130.

The second uneven structure 206 may be formed on the surface of the third nitride semiconductor layer 115 of the first uneven structure 203. The second uneven structure 206 may have an irregular and random shape, and the size of the second uneven structure 206 may be smaller than that of the first uneven structure 203.

For example, a height of a protrusion 1 of the second uneven structure 206 may be less than that of the protrusion 201 of the first uneven structure 203, and a depth of a recess 2 of the second uneven structure 206 may be less than that of the recess 2 of the first uneven structure 203.

Each of wet etch rates of the first nitride semiconductor layer 130 and the third nitride semiconductor layer 115 may be lower than a wet etch rate of the second nitride semiconductor layer 120.

For example, a ratio of the wet etch rate of the first or third nitride semiconductor layer 130 or 115 to the wet etch rate of the second nitride semiconductor layer 120 may be 1:5 to 1:100.

For example, each of the wet etch rates of the first to third nitride semiconductor layers 130, 120 and 115 may be a wet etch rate upon wet-etching using an etchant of an alkaline solution such as a KOH or NaOH solution.

When the ratio of wet etch rate is less than 1:5, the first and third nitride semiconductor layers cannot function as etch-stop films, and the light emitting structure 70 disposed thereunder may be thus damaged by etching, and when the ratio of the wet etch rate exceeds 1:100, the second uneven structure 206 may be not formed.

Each of the first nitride semiconductor layer 130 and the third nitride semiconductor layer 115 may have a thickness of 5 nm to 50 nm. The thickness of each of the first nitride semiconductor layer 130 and the third nitride semiconductor layer 115 is less than 5 nm, cracks may be generated during epi-growth and they cannot function as etch-stop films. In addition, when the thickness of each of the first nitride semiconductor layer 130 and the third nitride semiconductor layer 115 exceeds 50 nm, crystallinity of the light emitting structure 70 may be deteriorated.

Each of the first nitride semiconductor layer 130 and the third nitride semiconductor layer 115 may have a composition including aluminum, while the second nitride semiconductor layer 120 may have a composition excluding aluminum.

Alternatively, each of the first to third nitride semiconductor layers 130, 120 and 115 may have a composition including aluminum, and an aluminum content of each of the first nitride semiconductor layer 130 and the third nitride semiconductor layer 115 may be greater than that of the second nitride semiconductor layer 120.

For example, the first nitride semiconductor layer 130 may have a composition of AlₓGa₍₁₋ₓ₎N (0<x≦1), the third nitride semiconductor layer 115 may have a composition of Al_{y}Ga_{(1-y)}N (0<y≦1), and the second nitride semiconductor layer 120 may have a composition of Al_{z}Ga_{(1-z)}N (0≦z≦1), in which x and y are greater than z, with the proviso that x is equal to or different from y (x=y or x≠y).

As aluminum content in the composition of the first to third nitride semiconductor layers 130, 120 and 115 increases, wet etch rate may decrease.

In the present embodiment, light extraction efficiency can be improved by the first uneven structure 203 and the second uneven structure 206.

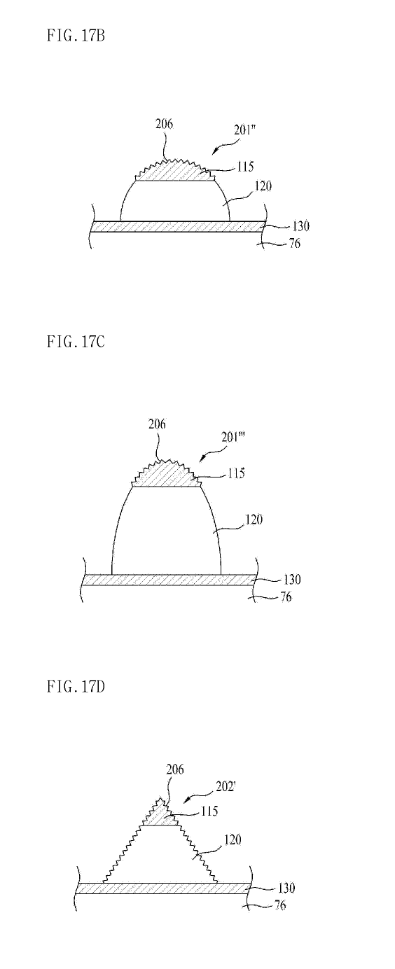

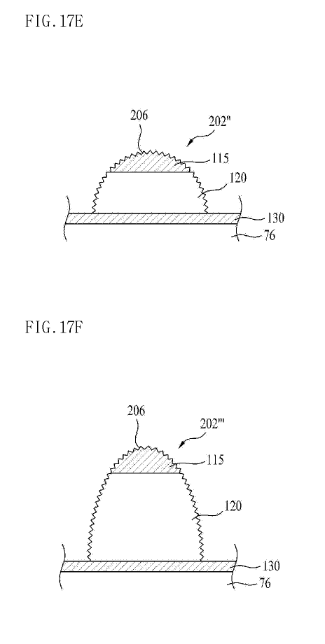

FIGS. 17A to 17C illustrate other embodiments 201′, 201″ and 201′″ of the protrusion 201 of the first uneven structure 203 shown in FIG. 10.

Referring to FIG. 17A, a protrusion 201′ of the first uneven structure 203 may have a conical shape and have a structure in which the second nitride semiconductor layer 120 and the third nitride semiconductor layer 115 are stacked. The third nitride semiconductor layer 115 may form a vertex of the protrusion 201′ and the second uneven structure 206 may be formed on the surface of the third nitride semiconductor layer 115.

Referring to FIGS. 17B and 17C, a protrusion 201″ or 201′″ of the first uneven structure 203 may have a dome shape, for example, a hemispherical shape shown in FIG. 17B, or an oval hemispherical shape shown in FIG. 17C and may have a structure in which the second nitride semiconductor layer 120 and the third nitride semiconductor layer 115 are stacked. The second uneven structure 206 may be formed on the surface of the third nitride semiconductor layer 115.

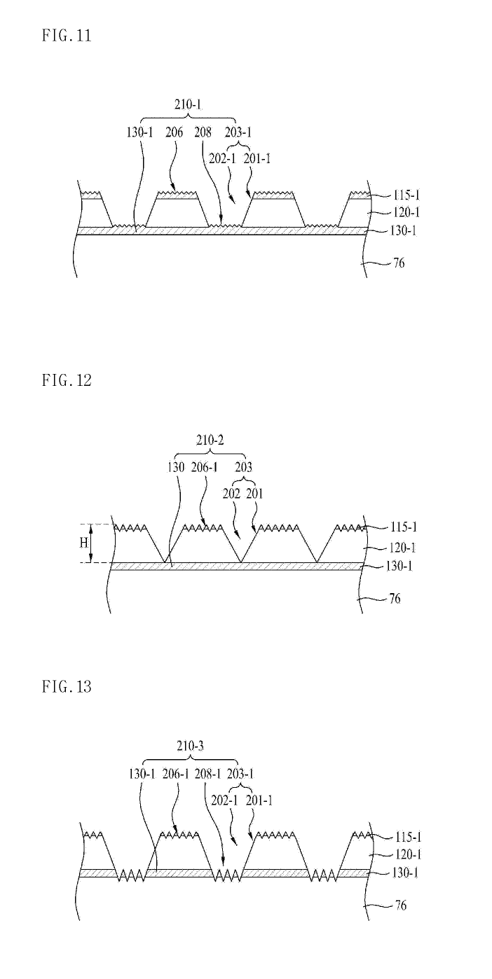

FIG. 11 illustrates a second embodiment 210-1 of the light extraction portion 210 shown in FIG. 1.

Referring to FIG. 11, the light extraction portion 210-1 may include the first nitride semiconductor layer 130, a first uneven structure 203-1, the second uneven structure 206, and a third uneven structure 208.

The first nitride semiconductor layer 130 may be disposed on the first conductivity-type semiconductor layer 76.

The first uneven structure 203-1 is a modification embodiment of the first uneven structure 203-1 shown in FIG. 10, which may include a protrusion 201-1 having a structure in which the second nitride semiconductor layer 120 and the third nitride semiconductor layer 115 are stacked, and a recess 202-1 exposing the first nitride semiconductor layer 130.

For example, the protrusion 201-1 may include a plurality of islands spaced apart from one another, and the recess 202-1 may be disposed between the islands and expose the first nitride semiconductor layer 130.

The second uneven structure 206 may be formed on the surface of the third nitride semiconductor layer 115 of the first uneven structure 203-1.

The third uneven structure 208 may be formed on the surface of the first nitride semiconductor layer 130 exposed by the recess 202-1 of the first uneven structure 203-1.

Each of the second uneven structure 206 and the third uneven structure 208 may have an irregular and random shape, and a size thereof may be smaller than that of the first uneven structure 203-1.

The second embodiment further includes the third uneven structure 208, thereby further improving light extraction efficiency, as compared to the first embodiment.

FIG. 12 illustrates a third embodiment 210-2 of the light extraction portion 210 shown in FIG. 1.

Referring to FIG. 12, the uneven structure 210-2 is a modification embodiment of the uneven structure 210 according to the first embodiment. The second uneven structure 206 according to the first embodiment is formed only on the surface of the third nitride semiconductor layer 115, while the second uneven structure 206-1 according to the third embodiment may be formed over the upper surface of the third nitride semiconductor layer 115 and the upper surface of the second nitride semiconductor layer 120. The recess of the second uneven structure 206-1 may expose the upper surface of the second nitride semiconductor layer 120.

FIG. 13 illustrates a fourth embodiment 210-3 of the light extraction portion 210 shown in FIG. 1.

Referring to FIG. 13, the light extraction portion 210-3 is a modification embodiment of the second embodiment 210-1. The third uneven structure 208 of the second embodiment is formed only on the surface of the first nitride semiconductor layer 130, while a third uneven structure 208-1 of the fourth embodiment is formed over the upper surfaces of the first nitride semiconductor layer 130 and the first conductivity-type semiconductor layer 76. The recess 202-1 of the third uneven structure 208-1 may expose the upper surface of the first conductivity-type semiconductor layer 76.

FIG. 14 illustrates a fifth embodiment 210-4 of the light extraction portion 210 shown in FIG. 1.

Referring to FIG. 14, the light extraction portion 210-4 is a modification embodiment of the second embodiment 210-1, and the fifth embodiment 210-4 includes the first nitride semiconductor layer 130, the first uneven structure 203-1, the second uneven structure 206, the third uneven structure 208 and a fourth uneven structure 209.

The fifth embodiment 210-4 may further include the fourth uneven structure 209, in addition to the components of the second embodiment 210-1.

The fourth uneven structure 209 may be formed on the side surface of the protrusion 201-1 of the first uneven structure 201-1. For example, the fourth uneven structure 209 may be formed on the side surface of the second nitride semiconductor layer 120 and on the side surface of the third nitride semiconductor layer 115. The fourth uneven structure 209 may have an irregular and random shape and a size thereof may be smaller than that of the first uneven structure 203-1.

FIGS. 17D to 17F illustrate other embodiments 202′, 202″ and 202′″ of the protrusion 201-1 of the first uneven structure 203-1 shown in FIG. 14.

Referring to FIG. 17D, a protrusion 202′ of the first uneven structure 203-1 may have a conical shape and have a structure in which the second nitride semiconductor layer 120 and the third nitride semiconductor layer 115 are stacked.

The third nitride semiconductor layer 115 may form a vertex of the protrusion 202′ and the second uneven structure 206 may be formed on the surface of the third nitride semiconductor layer 115 and on the surface of the second nitride semiconductor layer 120.

Referring to FIGS. 17E and 17F, a protrusion 202″ or 202′″ of the first uneven structure 203-1 may have a dome shape, for example, a hemispherical shape shown in FIG. 17E, or an oval hemispherical shape shown in FIG. 17F and may have a structure in which the second nitride semiconductor layer 120 and the third nitride semiconductor layer 115 are stacked. The second uneven structure 206 may be formed on the surface of the third nitride semiconductor layer 115 and on the surface of the second nitride semiconductor layer 120.

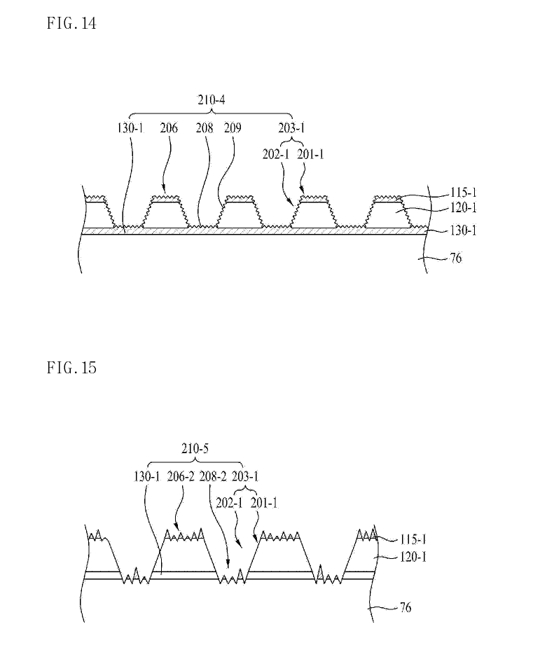

FIG. 15 illustrates a sixth embodiment 210-5 of the light extraction portion 210 shown in FIG. 1.

Referring to FIG. 15, the light extraction portion 210-5 is a modification embodiment of the third embodiment 210-2 and may include the first nitride semiconductor layer 130, the first uneven structure 203-1, a second uneven structure 206-2, and a third uneven structure 208-2.

The second uneven structure 206-2 may be formed over the upper surface of the third nitride semiconductor layer 115 and the upper surface of the second nitride semiconductor layer 120 and have an irregular and random shape.

The third uneven structure 208-1 may be formed over the first nitride semiconductor layer 130 and the upper surface of the first conductivity-type semiconductor layer 76 and have an irregular and random shape.

The protrusion 201 or 201-1 of the first uneven structure 203 or 203-1 shown in FIGS. 10 to 15 may have a frustum-of-pyramid or truncated cone shape, but not limited thereto. In another embodiment, the shape of the protrusion 201 or 201-1 may be any one of embodiments shown in FIGS. 17A to 17C.

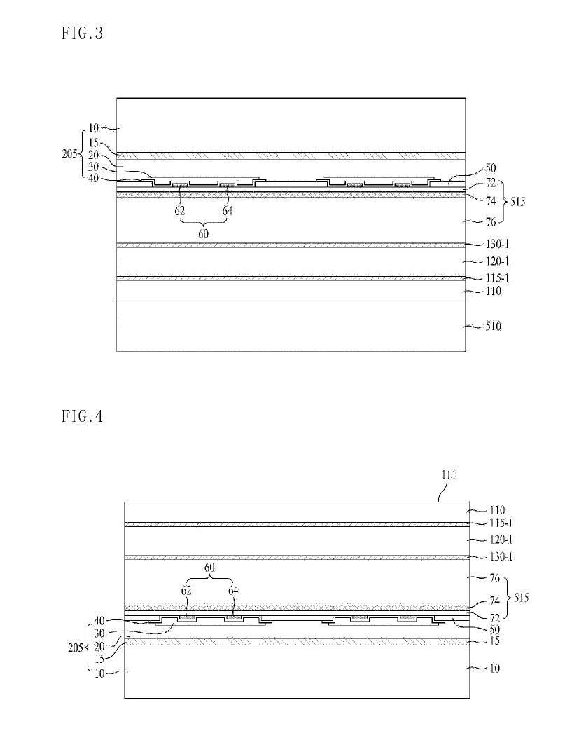

FIGS. 2 to 8 illustrate a method for fabricating a light emitting device according to an embodiment.

The same reference numbers as FIG. 1 designate the same components and items overlapping the description given above will be omitted or described in brief.

Referring to FIG. 2, a buffer layer 110, a first etch-stop layer 115-1, an intermediate layer 120-1, a second etch-stop layer 130-1 and a light emitting structure 515 are sequentially formed on a growth substrate 510.

The growth substrate 510 is suitable for growth of nitride semiconductor single crystals thereon. For example, the growth substrate 510 may be any one of a sapphire substrate, a silicon (Si) substrate, a zinc oxide (ZnO) substrate and a nitride semiconductor substrate, or a template substrate on which at least one of GaAs, GaP, InP, Ge, GaN, InGaN, AlGaN, and AlInGaN is stacked.

The buffer layer 110, the first etch-stop layer 115-1, the intermediate layer 120-1, and the second etch-stop layer 130-1, and the light emitting structure 515 may be sequentially formed using a method such as metal organic chemical vapor deposition (MOCVD), chemical vapor deposition (CVD), plasma-enhanced chemical vapor deposition (PECVD), molecular beam epitaxy (MBE), or hydride vapor phase epitaxy (HVPE). The light emitting structure 515 may include the first conductivity-type semiconductor layer 76, the active layer 74, and the second conductivity-type semiconductor layer 72.

The buffer layer 110 may be formed to reduce lattice mismatch between the growth substrate 510 and the light emitting structure 515 and thereby improve crystallinity of the light emitting structure 515.

The buffer layer 110 may include at least one of a nitride semiconductor layer including aluminum (for example, AlN, or AlGaN), and an undoped nitride layer (for example, undoped GaN).

The first wet etch rate of the first etch-stop layer 115-1 and the second wet etch rate of the second etch-stop layer 130-1 may be lower than the third wet etch rate of the intermediate layer 120-1.

For example, the first etch-stop layer 115-1 and the second etch-stop layer 130-1 may be nitride semiconductor layers including aluminum. The intermediate layer 120-1 may be a nitride semiconductor layer including no aluminum. Alternatively, the intermediate layer 120-1 may be a nitride semiconductor layer including aluminum, but may have a smaller aluminum content than the first and second etch-stop layers 115-1 and 130-1.

Referring to FIG. 3, a protective layer 50 patterned for division into a single chip region is formed on the light emitting structure 515. The protective layer 50 may be patterned to expose a part of the second conductivity-type semiconductor layer 72. The term “single chip region” used herein refers to a region divided for separation into individual chip units. The protective layer 50 may be formed on a circumference or edge of the single chip region by deposition using a mask pattern.

Next, a current blocking layer 60 is formed on the second conductivity-type semiconductor layer 72 exposed by the protective layer 50.

For example, a non-conductive material (for example, SiO₂) may be formed on the second conductivity-type semiconductor layer 72 and the non-conductive material may be patterned using a mask pattern (not shown) to form the current blocking layer 60. When the protective layer 50 is formed of a non-conductive material, the protective layer 50 and the current blocking layer 60 may be formed of the same material as the protective layer 50, and the protective layer 50 and the current blocking layer 60 may be simultaneously formed using the same mask pattern.

Next, a second electrode 205 is formed on the second conductivity-type semiconductor layer 72 and the current blocking layer 60. The second electrode 205 may include an ohmic layer 40, a reflective layer 30, a diffusion preventing layer 20, an adhesive layer 15, and a support substrate 10, as described below.

The ohmic layer 40 is formed on the second conductivity-type semiconductor layer 72 and the current blocking layer 60. For example, the ohmic layer 40 may be formed on the second conductivity-type semiconductor layer 72 as well as on the side surface and the upper surface of the current blocking layer 60, and at edges of the side surface and the upper surface of the protective layer.

In addition, the reflective layer 30 is formed on the ohmic layer 40. For example, the ohmic layer 40 and the reflective layer 30 may be formed by any one method of E-beam deposition, sputtering, and plasma enhanced chemical vapor deposition (PECVD). The ohmic layer 40 and the reflective layer 30 having various structures according to formed area may be formed.

In addition, the diffusion preventing layer 20 is formed on the reflective layer 30 and the protective layer 50. The diffusion preventing layer 20 may be formed such that it contacts the reflective layer 30, the protective layer 50, or the ohmic layer 40.

Next, the support substrate 10 is adhered to the diffusion preventing layer 20 using the adhesive layer 15 as a medium. For example, adhesion of the support substrate 10 to the diffusion preventing layer 20 can be carried out by forming a first adhesion metal (not shown) on one surface of the support substrate 10, forming a second adhesion metal (not shown) on the surface of the diffusion preventing layer 20, pressing the first adhesion metal and the second adhesion metal at a high temperature and a high pressure, and cooling the pressed first and second adhesion metals to room temperature. At this time, the pressed first and second adhesion metals may constitute the adhesive layer 15.

Referring to FIG. 4, the growth substrate 510 is removed from the light emitting structure 515 using a method such as laser lift off or chemical lift off. FIG. 4 illustrates the structure shown in FIG. 3 in reverse.

By removing the growth substrate 510, a surface 111 of the buffer layer 110 having contacted the growth substrate 510 may be exposed.

Referring to FIG. 5, a mask pattern 140 is formed on one surface 111 of the buffer layer 110. At this time, the mask pattern 140 may be a regular or irregular pattern.

For example, the mask pattern 140 may be formed on the buffer layer 110 by a photolithographic process. The shape of the groove 150 can be controlled by controlling the shape of the mask pattern 140 and conditions of dry etching process, and the protrusion of the first uneven structure 203 or 203-1 may be formed to have any one shape of embodiments 201, 201′, 201″, and 201′″.

Next, the buffer layer 110, the first etch-stop layer 115-1, and the intermediate layer 120-1 are partially dry etched using the mask pattern 140 as an etching mask to form the groove 150. In this case, the groove 150 may include a plurality of grooves and the grooves may be spaced apart from one another.

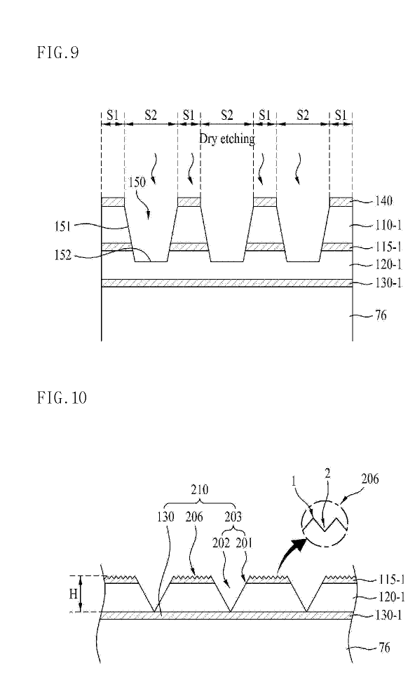

FIG. 9 illustrates an enlarged view of the groove 150 formed by dry etching of FIG. 5.

Referring to FIG. 9, the mask pattern 140 may be disposed on a first region S1 of the buffer layer 110-1 and expose a second region S2 of the buffer layer 110-1.

Dry etching enables partial removal of the first region S1 of the buffer layer 110-1, and the first etch-stop layer 115-1 and the intermediate layer 120-1 disposed under the first region S1, and formation of the groove 150 having a side wall 151 and a bottom 152.

The second region S2 of the buffer layer 110-1, and a part of the first etch-stop layer 115-1 and a part of the intermediate layer 120-1 disposed under the second region S2, each avoiding etching by the mask pattern 140, may remain.

The groove 150 may pass through the buffer layer 110-1 and the first etch-stop layer 115-1, and the bottom 152 of the groove 150 may be disposed under the remaining first etch-stop layer 115-1.

For example, the bottom 152 of the groove 150 may be disposed between the second etch-stop layer 130-1 and the remaining first etch-stop layer 115-1.

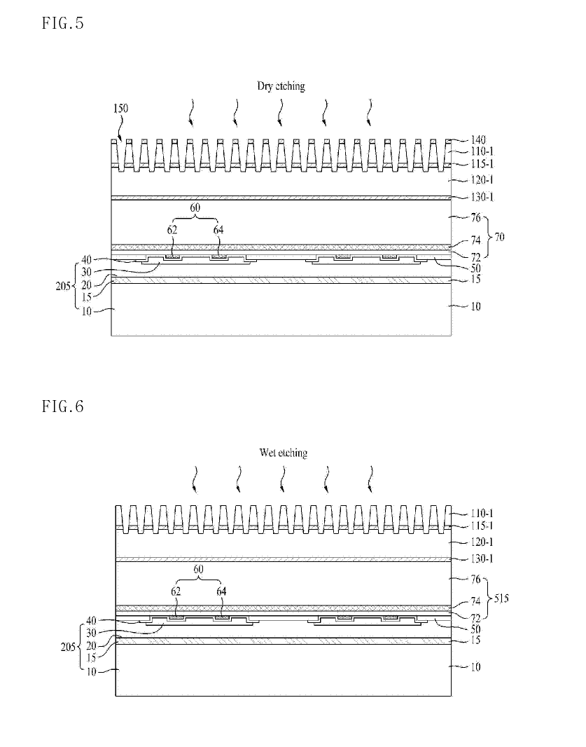

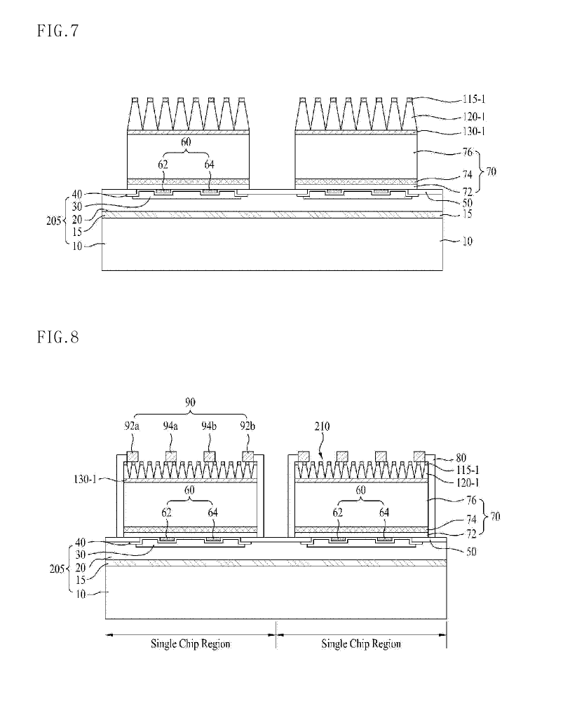

Next, referring to FIG. 6, the remaining mask pattern 140 may be removed by an ashing or stripping process. As a result of removal of the remaining mask pattern 140, the buffer layer 110-1 that remains on the first region S1 may be exposed.

The remaining buffer layer 110-1 and the remaining intermediate layer 120-1 are wet-etched using the first etch-stop layer 115-1 and the second etch-stop layer 130-1 using etching masks until the first etch-stop layer 115-1 and the second etch-stop layer 130-1 are exposed.

For example, the remaining buffer layer 110-1 and the remaining intermediate layer 120-1 may be wet-etched using an alkaline solution such as a KOH or NaOH solution as an etchant.

The wet-etching of the remaining intermediate layer 120-1 may be stopped by the second etch-stop layer 130-1. This is because the wet etch rate of the second etch-stop layer 130-1 is lower than that of the remaining intermediate layer 120-1.

In addition, wet-etching of the remaining buffer layer 110-1 may be stopped by the remaining first etch-stop layer 115-1. This is because the wet etch rate of the first etch-stop layer 115-1 is lower than wet etch rates of the remaining buffer layer 110-1 and the remaining intermediate layer 120-1.

FIG. 10 illustrates an embodiment of the light extraction portion 210 formed by wet-etching of FIG. 6. Here, the first etch-stop layer 115-1 may correspond to the third nitride semiconductor layer of FIG. 1, the intermediate layer 120-1 may correspond to the second nitride semiconductor layer of FIG. 1, and the second etch-stop layer 130-1 may correspond to the first nitride semiconductor layer of FIG. 1.

Referring to FIG. 10, the first uneven structure 203 and the second uneven structure 206 may be formed on the second etch-stop layer 130-1 by wet etching. The first uneven structure 203 may include the remaining second nitride semiconductor layer 120 and the third nitride semiconductor layer 115 by wet etching and the second uneven structure 203 may be formed on the surface of the third nitride semiconductor layer 115.

The remaining buffer layer 110-1 disposed on the remaining first etch-stop layer 115-1 may be removed by wet etching and the remaining first etch-stop layer 115-1 may be exposed by wet etching.

Since the remaining first etch-stop layer 115-1 functions to block wet etching, a part of the intermediate layer 120-1 disposed under the remaining first etch-stop layer 115-1 may avoid wet etching.

The remaining first etch-stop layer 115-1 and the part of the intermediate layer 120-1 disposed thereunder, each avoiding wet etching, may constitute the protrusion 201 of the first uneven structure 203.

The other part of the intermediate layer 120-1 disposed under the bottom 152 of the groove 150 may be removed by wet etching and the second etch-stop layer 130-1 may be exposed by wet etching.

The other part of the intermediate layer 120-1 disposed under the bottom 152 of the groove 150 removed by wet etching may constitute the recess 202 of the first uneven structure 203.

Since the second etch-stop layer 130-1 functions to block wet etching, the first conductivity-type semiconductor layer 76 disposed under the second etch-stop layer 130-1 may also avoid wet etching.

The second uneven structure 206 having an irregular shape may be formed on the surface of the remaining first etch-stop layer 115-1 by wet etching.

The size of the second uneven structure 206 may be smaller than that of the first uneven structure 203. For example, the height of the protrusion 1 of the second uneven structure 206 may be lower than that of the protrusion 201 of the first uneven structure 203, and the depth of the recess 2 of the second uneven structure 206 may be less than that of the recess 202 of the first uneven structure 203.

In the present embodiment, the height of the protrusion 201 of the first uneven structure 203 can be easily controlled by the thickness of the intermediate layer 120-1 disposed between the first etch-stop layer 115-1 and the second etch-stop layer 130-1. For example, the height of the protrusion 201 of the first uneven structure 203 may be formed in proportion to the thickness of the intermediate layer 120-1.

Since the wet etch rates of the first etch-stop layer 115-1 and the second etch-stop layer 130-1 are lower than the wet etch rate of the intermediate layer 120-1, in the present embodiment, the first uneven structure 203 may be formed such that the height of the protrusion 201 and the depth of the recess 202 are entirely uniform, thereby uniformly improving light extraction efficiency throughout the light emitting region.

FIG. 11 illustrates a second embodiment 210-1 of light extraction portion 210 formed by wet etching of FIG. 6. Here, the first etch-stop layer 115-1 may correspond to the third nitride semiconductor layer of FIG. 1, the intermediate layer 120-1 may correspond to the second nitride semiconductor layer of FIG. 1, and the second etch-stop layer 130-1 may correspond to the first nitride semiconductor layer of FIG. 1.

Referring to FIG. 11, the second etch-stop layer 130-1 may be exposed by wet etching and the third uneven structure 208 may be formed on the surface of the exposed second etch-stop layer 130-1 by wet etching.

For example, the protrusion 201-1 of the first uneven structure 203-1 formed by wet etching may include a plurality of islands spaced apart from one another and the recess 202-1 may be disposed between the islands and expose the second etch-stop layer 130-1.

FIG. 12 illustrates a third embodiment 210-2 of the light extraction portion 210 formed by wet etching of FIG. 6. Referring to FIG. 12, the second uneven structure 206-1 can be formed at the upper surface of the first etch-stop layer 115-1 and the intermediate layer 120-1 by increasing intensity or time of wet etching as compared to the first embodiment. In this case, the recess of the second uneven structure 206-1 may expose a part of the upper surface of the intermediate layer 120-1.

FIG. 13 illustrates a fourth embodiment 210-3 of the light extraction portion 210 formed by wet etching of FIG. 6.

The third uneven structure 208-1 can be formed at the upper surfaces of the second etch-stop layer 130-1 and the first conductivity-type semiconductor layer 76 by increasing intensity or time of wet etching as compared to the second embodiment. In this case, the recess of the second uneven structure 206-1 may expose a part of the upper surface of the first conductivity-type semiconductor layer 76.

FIG. 14 illustrates a fifth embodiment 210-4 of the light extraction portion 210 formed by wet etching of FIG. 6.

The side surface of the protrusion 201-1 of the first uneven structure 203-1 may be wet etched and the fourth uneven structure 209 may be formed by wet etching.

FIG. 15 illustrates a sixth embodiment 210-5 of the light extraction portion 210 formed by wet etching of FIG. 6.

Next, referring to FIG. 7, the first etch-stop layer 115-1, the intermediate layer 120-1, the second etch-stop layer 130-1, and the light emitting structure 515 are isolation-etched along the single chip region to perform separation into a plurality of light emitting structures 70.

For example, the isolation etching may be carried out by dry etching such as inductively coupled plasma (ICP) and a part of the protective layer 50 may be exposed by isolation etching.

Next, referring to FIG. 8, a passivation layer 80 is formed on the protective layer 50 and the light emitting structures 70, and the passivation layer 80 is selectively removed to expose the light extraction portion 210. For example, the passivation layer 80 disposed on the light emitting structure 70 may be selectively removed to expose the first etch-stop layer 115-1. In addition, a first electrode 90 is formed on the upper surface of the exposed light extraction portion 210.

The first electrode 90 may be formed to have a predetermined pattern for current dispersion.

For example, the first electrode 90 may include a pad portion (not shown) to which a wire (not shown) is bonded, and a branch electrode connected to the pad portion. The branch electrode may include external electrodes 92a to 92d, and internal electrodes 94a to 94c. The external electrodes 92a to 92d may be disposed at an edge of the light emitting structure 70 and the internal electrodes 94a to 94c may be disposed within the external electrodes 92a to 92d. The external electrodes 92a to 92d may overlap the protective layer 80 in a vertical direction and the internal electrodes 94a to 94c may overlap the current blocking layer 60 in a vertical direction. The vertical direction as used herein may refer to a direction extending from the second conductivity-type semiconductor layer 72 to the first conductivity-type semiconductor layer 76.

Next, a plurality of light emitting devices may be fabricated by separation into single chip regions using a chip separation process. In this case, the structure of each light emitting device may correspond to the embodiment 100 shown in FIG. 1.

The chip separation process may, for example, be breaking including applying physical force using a blade to separate chips, laser scribing including radiating laser to boundaries between chips to separate the chips, and etching including wet etching or dry etching.

FIG. 18 shows simulation results of light extraction efficiency of the light emitting device according to height of the protrusion 201 shown in FIG. 10. The x axis represents a height of the protrusion and the y axis represents light extraction efficiency.

The protrusion 201 of the first uneven structure 203 of the light extraction portion 210 shown in FIG. 18 has a frustum-of-hexagonal pyramid shape shown in FIG. 16A and an area fill factor (AFF) of 100%. Here, the area fill factor (AFF) may be a ratio of an area of the protrusion (for example, 201) of the uneven structure with respect to the total area of the surface of a layer (for example, 130-1) having an uneven structure (for example, 203) formed thereon.

f1 may be a light extraction efficiency when an inclination angle of the side surface of the first uneven structure 203 is 50°, and f2 may be a light extraction efficiency when an inclination angle of the side surface of the first uneven structure 203 is 60°.

Here, the inclination angle may mean an angle at which the side surface of the frustum-of-hexagonal pyramid is inclined, based on the upper (or lower) surface of the frustum-of-hexagonal pyramid. For example, the inclination angle may be an angle at which the side surface of the protrusion 201 is inclined based on the surface of the first nitride semiconductor layer 130.

As can be seen from FIG. 18, a height of the first uneven structure providing an optimum light extraction efficiency is present depending on the shape of the first uneven structure 203.

For example, it can be seen that, in case of f1, light extraction efficiency is a maximum of about 0.63 to 0.64, when the height of the protrusion 201 of the first uneven structure 203 is 0.7 um to 0.9 um and.

In case of f2, light extraction efficiency is a maximum of 0.6 to 0.61, when the height of the protrusion 201 of the first uneven structure 203 is 1.0 um to 1.2 um.

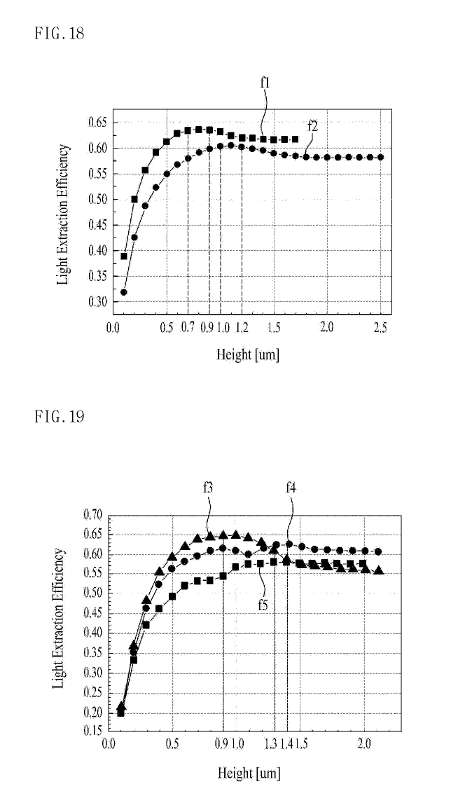

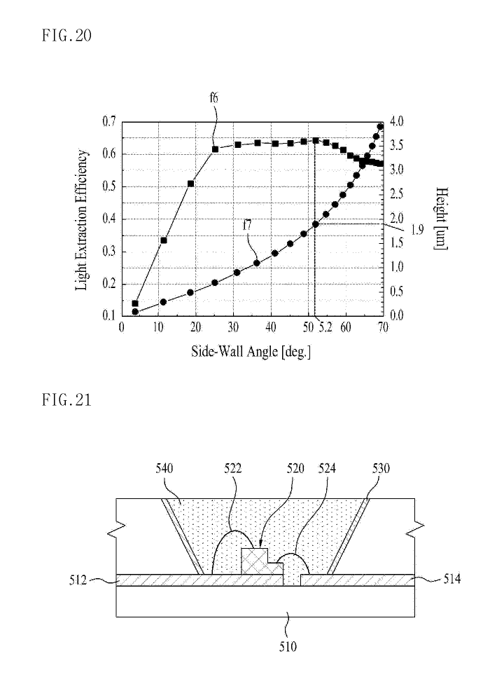

FIG. 19 shows simulation results of light extraction efficiency of the light emitting device according to height of a protrusion having a hemispherical or oval hemispherical shape. The x axis represents height h of the protrusion and the y axis represents light extraction efficiency.

The light extraction portion 210-1 of FIG. 19 may have an island shape shown in FIG. 11, and respective protrusions shown in f3 to f5 according to the height h may have a hemispherical or oval hemispherical shape.

f3 has a horizontal radius R of 1.5 um and an area fill factor (AFF) of 90%. In addition, f4 has a horizontal radius R of 1.22 um and an area fill factor (AFF) of 60%. In addition, f5 has a horizontal radius R of 0.9 um and an area fill factor (AFF) of 32.6%.

In case of f3, light extraction efficiency is a maximum of about 0.64, when the height h of the protrusion of the first uneven structure is 0.9 um to 1.0 um.

In addition, in case of f4, light extraction efficiency is a maximum of about 0.625, when the height h of the protrusion of the first uneven structure is 1.3 um to 1.4 um.

In addition, in case of f5, light extraction efficiency is a maximum of about 0.57 when the height h of the protrusion of the first uneven structure is 1.3 um to 2.0 um.

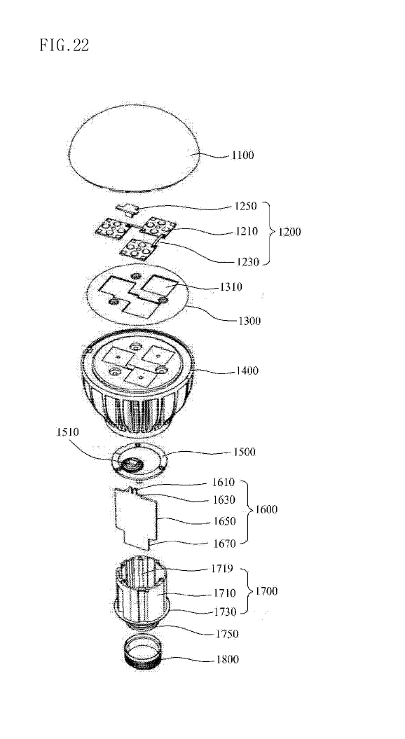

FIG. 20 shows simulation results of light extraction efficiency of the light emitting device according to height of a protrusion having a truncated cone shape. The x axis represents an angle (single-wall angle) at which the sidewall of the truncated cone is inclined, based on the lower surface of the truncated cone.

f6 shows variation in light extraction efficiency according to varied angle of the side surface of the truncated cone when the area fill factor (AFF) is set to 90% and the radius of the lower surface of the truncated cone is set to 3 um. f7 represents a height of the truncated cone corresponding to the angle of the side surface of the truncated cone of f6. Here, the height of the truncated cone may be the distance from the lower surface of the truncated cone to a vertex of the truncated cone.

When the lower surface of the truncated cone has a predetermined radius (for example, 3 um), light extraction efficiency may be changed according to the angle of the side surface of the truncated cone, and the angle of the side surface of the truncated cone providing maximum light extraction efficiency and the height of the truncated cone corresponding thereto can be obtained.

As can be seen from FIG. 20, when the area fill factor (AFF) is set to 90% and the radius of the lower surface of the truncated cone is set to 3 um, light extraction efficiency is maximized in a case where an angle of the side surface of the truncated cone is about 52°. In this case, it can be seen that the height of the truncated cone providing maximum light extraction efficiency is 1.9 um.

In the present embodiment, the height of the protrusion 201 of the first uneven structure 203 can be easily controlled depending on the thickness of the intermediate layer 120-1 disposed between the first etch-stop layer 115-1 and the second etch-stop layer 130-1. That is, in the present embodiment, the height of the first uneven structure 203 providing optimum light extraction efficiency can be easily controlled, since the thickness of the intermediate layer 120-1 determines the height of the uneven structure. In addition, in the present embodiment, light extraction efficiency can be further improved owing to the second uneven structure 206 and/or the third uneven structure 208 formed by wet etching.

FIG. 21 illustrates a light emitting device package according to another embodiment.

Referring to FIG. 21, the light emitting device package includes a package body 510, a first metal layer 512, a second metal layer 514, a light emitting device 520, a reflective plate 530, a wire 530, and a resin layer 540.

The package body 510 may be a substrate having high insulating property or high thermal conductivity, such as a silicon-based wafer level package, a silicon substrate, a silicon carbide (SiC) substrate or an aluminum nitride (AlN) substrate, and may have a structure in which a plurality of substrates are stacked. Embodiments are not limited to the aforementioned material, structure and shape of the package body 510.

The package body 510 may have a cavity having side surfaces and a bottom surface at a side of the upper surface of the package body 510. In this case, the sidewalls of the cavity may be inclined.

The first metal layer 512 and the second metal layer 514 are disposed on the surface of the package body 510 so as to be electrically isolated from each other in consideration of heat dissipation or mounting of the light emitting device. The light emitting device 520 is electrically connected to the first metal layer 512 and the second metal layer 514. In this case, the light emitting device 520 may be the embodiment 100.

The reflective plate 530 may be disposed on the sidewalls of the cavity of the package body 510 so as to guide light emitted from the light emitting device 520 in a designated direction. The reflective plate 530 may be formed of a light reflecting material, for example, a coated metal or a metal flake.

The resin layer 540 surrounds the light emitting device 520 located within the cavity of the package body 510 to protect the light emitting device 520 from external environment. The resin layer 540 may be formed of a colorless and transparent polymer resin, such as epoxy or silicone. The resin layer 540 may include a phosphor so as to change the wavelength of light emitted from the light emitting device 520.

A plurality of light emitting device packages including the light emitting device package according to the present embodiment may be arrayed on a substrate and optical members, such as a light guide panel, prism sheets, a diffusion sheet and the like, may be disposed on the optical path of the light emitting device packages. Such light emitting device packages, substrate and optical members may function as backlight units.

Another embodiment may be implemented by a display device, an indication device or a lighting system including the light emitting device or the light emitting device package according to the afore-mentioned embodiments. For example, the lighting system may include a lamp, streetlamp or the like.

FIG. 22 illustrates a lighting device including the light emitting device according to another embodiment.

Referring to FIG. 22, the lighting device may include a cover 1100, a light source module 1200, a heat dissipater 1400, a power supply unit 1600, an inner case 1700, and a socket 1800. In addition, the lighting device according to the present embodiment may further include one or more of a member 1300 and a holder 1500.

The light source module 1200 may include the light emitting device 100 according to the embodiment, or the light emitting package shown in FIG. 17.

The cover 1100 may have a hollow bulb or hemispherical shape having an opening. The cover 1100 may be optically coupled to the light source module 1200. For example, the cover 1100 may diffuse, scatter, or excite light supplied from the light source module 1200. The cover 1100 may be a kind of optical member. The cover 1100 may be coupled to the heat dissipater 1400. The cover 1100 may have a coupling portion coupled to the heat dissipater 1400.

The inner surface of the cover 1100 may be coated with a ivory white paint. The ivory white paint may include a light diffuser diffusing light. Surface roughness of the inner surface of the cover 1100 may be greater than surface roughness of the outer surface of the cover 1100. This serves to sufficiently scatter and diffuse light emitted from the light source module 1200 so as to discharge the light to the outside.

The cover 1100 may be formed of glass, plastic, polypropylene (PP), polyethylene (PE), polycarbonate (PC), etc. Here, polycarbonate (PC) has excellent light resistance, heat resistance, and strength. The cover 1100 may be transparent such that the light source module 1200 can be seen from the outside, but not limited thereto.

Alternatively, the cover 1100 may be opaque. The cover 1100 may be formed by blow molding.

The light source module 1200 may be disposed on one surface of the heat dissipater 1400. Therefore, heat generated by the light source module 1200 is conducted to the heat dissipater 1400. The light source module 1200 may include light source units 1210, connection plates 1230, and a connector 1250.

The member 1300 may be disposed on the upper surface of the heat dissipater 1400, and include guide recesses 1310 into which the light source units 1210 and the connector 1250 are inserted. The guide recesses 1310 may correspond to or may be aligned with substrates of the light source units 1210 and the connector 1250.

A light reflecting material may be applied to or coated on the surface of the member 1300.

For example, a white paint may be applied to or coated on the surface of the member 1300. The member 1300 reflects light, which has been reflected by the inner surface of the cover 1100 and has returned toward the light source module 1200, toward the cover 1100 again. Therefore, it is possible to enhance light efficiency of the lighting device according to the present embodiment.

The member 1300 may be formed of, for example, an insulating material. The connection plates 1230 of the light source module 1200 may include an electrically conductive material. Therefore, electrical contact between the heat dissipater 1400 and the connection plates 1230 may occur. The member 1300 formed of an insulating material may prevent electrical short-circuit between the connection plates 1230 and the heat dissipater 1400. The heat dissipater 1400 receives heat from the light source module 1200 and the power supply unit 1600, and dissipates the heat.

The holder 1500 closes an accommodation groove 1719 of an insulating portion 1710 of the inner case 1700. Therefore, the power supply unit 1600 accommodated in the insulating portion 1710 of the inner case 1700 may be hermetically sealed. The holder 1500 may have a guide protrusion 1510. The guide protrusion 1510 may be provided with a hole through which a protrusion 1610 of the power supply unit 1600 passes.

The power supply unit 1600 processes or converts an electrical signal supplied from the outside, and then supplies the same to the light source module 1200. The power supply unit 1600 may be accommodated in the accommodation groove 1719 of the inner case 1700 and be hermetically sealed within the inner case 1700 by the holder 1500. The power supply unit 1600 may include the protrusions 1610, a guide portion 1630, a base 1650, and an extension portion 1670.

The guide portion 1630 protrudes outward from one side of the base 1650. The guide portion 1630 may be inserted into the holder 1500. A plurality of elements may be disposed on one surface of the base 1650. For example, the elements may include an AC/DC converter to convert AC power supplied from an external power source into DC power, a driving chip to control driving of the light source module 1200, and an electrostatic discharge (ESD) protection element to protect the light source module 1200, without being limited thereto.

The extension portion 1670 may protrude outward from the other side of the base 1650. The extension portion 1670 may be inserted into a connection part 1750 of the inner case 1700 and receive an electrical signal from the outside. For example, the extension portion 1670 may have a width equal to or less than the width of the connection part 1750 of the inner case 1700. One end of each of a positive (+) electric wire and a negative (−) electric wire may be electrically connected to the extension portion 1670, and the other end of each of the positive (+) electric wire and the negative (−) electric wire may be electrically connected to the socket 1800.

The inner case 1700 may include a molding portion in addition to the power supply unit 1600 therein. The molding portion is formed by hardening a molding liquid and serves to fix the power supply unit 160 within the inner case 1700.

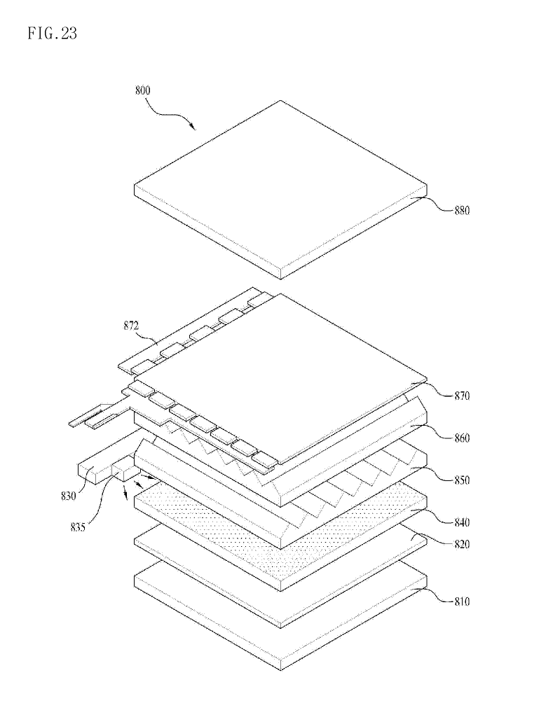

FIG. 23 illustrates a display device including the light emitting device according to another embodiment.

Referring to FIG. 10, the display device 800 may include a bottom cover 810, a reflective plate 820 disposed on the bottom cover 810, a light emitting module 830 or 835 to emit light, a light guide panel 840 being disposed in front of the reflective plate 820 and guiding light emitted from the light emitting module 830 or 835 to front of the display device 800, optical sheets including prism sheets 850 and 860 disposed in front of the light guide panel 840, a display panel 870 disposed in front of the optical sheets, an image signal output circuit 872 being connected to the display panel 870 and supplying an image signal to the display panel 870, and a color filter 880 disposed in front of the display panel 870. Here, the bottom cover 810, the reflective plate 820, the light emitting module 830 or 835, the light guide panel 840 and the optical sheets may constitute a backlight unit.

The light emitting module may include light emitting device packages 835 mounted on a substrate 830. Here, a PCB or the like may be used as the substrate 830. The light emitting device package 835 may be the embodiment shown in FIG. 17.

The bottom cover 810 may accommodate elements within the display device 800. In addition, the reflective plate 820 may be provided as a separate element, as shown in the drawing, or be provided by coating the rear surface of the light guide panel 840 or the front surface of the bottom cover 810 with a material having high reflectivity.

Here, the reflective plate 820 may be formed of a material which has high reflectivity and can be used as an ultra-thin type, and be formed of polyethylene terephthalate (PET).

The light guide panel 840 may be formed of polymethylmethacrylate (PMMA), polycarbonate (PC), or polyethylene (PE).

The first prism sheet 850 is formed by applying a light-transmitting and elastic polymer to a surface of a support film. The polymer may have a prism layer in which a plurality of 3D structures are repeatedly formed. Here, the structures may be provided as a stripe pattern in which ridges and valleys are repeatedly formed, as shown in the drawing.

In addition, the direction of ridges and valleys on one surface of the support film of the second prism sheet 860 may be perpendicular to the direction of the ridges and valleys on one surface of the support film in the first prism sheet 850.

This serves to uniformly disperse light transmitted from the light source module and the reflective sheet 820 in all directions of the display panel 870.

Although not shown, a diffusion sheet may be disposed between the light guide panel 840 and the first prism sheet 850. The diffusion sheet may be formed of a polyester or polycarbonate-based material and maximally increase the projection angle of light incident from the backlight unit by refraction and scattering. Further, the diffusion sheet may include a support layer including a light diffuser, and a first layer and a second layer that are formed on a light-emitting surface (a direction toward the first prism sheet) and a light-receiving surface (a direction toward the reflective sheet) and not include a light diffuser.

In this embodiment, the diffusion sheet, the first prism sheet 850 and the second prism sheet 860 constitute the optical sheets. However, the optical sheets may include other combinations, for example, a micro-lens array, a combination of a diffusion sheet and a micro-lens array, or a combination of one prism sheet and a micro-lens array.

As the display panel 870, a liquid crystal display panel may be disposed. Further, in addition to the liquid crystal display panel, other kinds of display devices requiring light sources may be provided.

Features, structures and effects and the like described associated with the embodiments above are incorporated into at least one embodiment of the present disclosure, but are not limited to only one embodiment. Furthermore, features, structures and effects and the like exemplified associated with respective embodiments can be implemented in other embodiments by combination or modification by those skilled in the art. Therefore, contents related to such combinations and modifications should be construed as falling within the scope of the present disclosure.

### INDUSTRIAL APPLICABILITY

The embodiments may be used for lighting devices and display devices.

1. A light emitting device comprising:
a light emitting structure comprising a first conductivity-type semiconductor layer, an active layer and a second conductivity-type semiconductor layer; and
a light extraction portion disposed on the light emitting structure,
wherein the light extraction portion comprises:
a first nitride semiconductor layer being disposed on the first conductivity-type semiconductor layer and having a first wet etch rate; and
a second nitride semiconductor layer being disposed on the first nitride semiconductor layer and having a second wet etch rate, and a third nitride semiconductor layer having a third wet etch rate,
wherein the first wet etch rate and the third wet etch rate are lower than the second wet etch rate.

2. The light emitting device according to claim 1, wherein the light extraction portion further comprises:
a first uneven structure comprising a protrusion and a recess, the protrusion having a structure in which the second nitride semiconductor layer and the third nitride semiconductor layer are stacked; and
a second uneven structure formed on the third nitride semiconductor layer of the first uneven structure.

3. The light emitting device according to claim 1, wherein each of the first nitride semiconductor layer and the third nitride semiconductor layer has a composition comprising aluminum and the second nitride semiconductor layer has a composition excluding aluminum.

4. The light emitting device according to claim 1, wherein each of the first to third nitride semiconductor layers has a composition comprising aluminum and an aluminum content of each of the first nitride semiconductor layer and the third nitride semiconductor layer is greater than an aluminum content of the second nitride semiconductor layer.

5. The light emitting device according to claim 1, wherein the composition of the first nitride semiconductor layer is AlₓGa₍₁₋ₓ₎N (0<x≦1), the composition of the third nitride semiconductor layer is Al_{y}Ga_{(1-y)}N (0<y≦1), and the composition of the second nitride semiconductor layer is Al_{z}Ga_{(1-z)}N (0≦z≦1), in which x and y are greater than z.

6. The light emitting device according to claim 2, wherein the first uneven structure has a regular pattern shape and the second uneven structure has an irregular pattern shape.

7. The light emitting device according to claim 2, wherein the recess of the first uneven structure exposes an upper surface of the first nitride semiconductor layer.

8. The light emitting device according to claim 7, wherein the light extraction portion further comprises a third uneven structure formed on the upper surface of the first nitride semiconductor layer exposed by the recess of the first uneven structure.

9. The light emitting device according to claim 1, wherein each of the first nitride semiconductor layer and the third nitride semiconductor layer has a thickness of 5 nm to 50 nm.

10. The light emitting device according to claim 1, wherein a ratio of the first wet etch rate to the second wet etch rate, and a ratio of the third wet etch rate to the second wet etch rate are 1:5 to 1:100.

11. The light emitting device according to claim 1, further comprising:
a first electrode disposed on the light extraction portion; and
a second electrode disposed under the second conductivity-type semiconductor layer.

12. A light emitting device comprising:
a light emitting structure comprising a first conductivity-type semiconductor layer, an active layer and a second conductivity-type semiconductor layer; and
a light extraction portion disposed on the light emitting structure,
wherein the light extraction portion comprises:
a first nitride semiconductor layer disposed on the light emitting structure;
a first uneven structure comprising a protrusion and a recess, the protrusion comprising a second nitride semiconductor layer disposed on the first nitride semiconductor layer and a third nitride semiconductor layer disposed on the first nitride semiconductor layer; and
a second uneven structure formed on a surface of the third nitride semiconductor layer of the first uneven structure,
wherein the first nitride semiconductor layer has a first wet etch rate, the second nitride semiconductor layer has a second wet etch rate, the third nitride semiconductor layer has a third wet etch rate, and the first wet etch rate and the third wet etch rate are lower than the second wet etch rate.

13. The light emitting device according to claim 12, wherein each of the first nitride semiconductor layer and the third nitride semiconductor layer has a composition comprising aluminum and the second nitride semiconductor layer has a composition excluding aluminum.

14. The light emitting device according to claim 12, wherein each of the first to third nitride semiconductor layers has a composition comprising aluminum and an aluminum content of each of the first nitride semiconductor layer and the third nitride semiconductor layer is greater than an aluminum content of the second nitride semiconductor layer.

15. The light emitting device according to claim 12, wherein the composition of the first nitride semiconductor layer is AlₓGa₍₁₋ₓ₎N (0<x≦1), the composition of the third nitride semiconductor layer is Al_{y}Ga_{(1-y)}N (0<y≦1), and the composition of the second nitride semiconductor layer is Al_{z}Ga_{(1-z)}N (0≦z≦1), in which x and y are greater than z.

16. The light emitting device according to claim 12, wherein the first uneven structure has a regular pattern shape and the second uneven structure has an irregular pattern shape.

17. The light emitting device according to claim 12, wherein the recess of the first uneven structure exposes an upper surface of the first nitride semiconductor layer.

18. The light emitting device according to claim 17, wherein the light extraction portion further comprises a third uneven structure formed on the upper surface of the first nitride semiconductor layer exposed by the recess of the first uneven structure.

19. The light emitting device according to claim 12, wherein the light extraction portion further comprises a fourth uneven structure formed on a side surface of the protrusion.

20-22. (canceled)

23. A light emitting device comprising:
a light emitting structure comprising a first conductivity-type semiconductor layer, an active layer and a second conductivity-type semiconductor layer; and
a light extraction portion disposed on the light emitting structure,
wherein the light extraction portion comprises:
a second etch stop layer disposed on the light emitting structure;
a first uneven structure comprising a protrusion and a recess, the protrusion comprising a intermediate layer disposed on the second etch stop layer and a first etch stop layer disposed on the second etch stop layer; and
a second uneven structure formed on a surface of the first etch stop layer of the first uneven structure,
wherein the second etch stop layer has a first wet etch rate, the intermediate layer has a second wet etch rate, the first etch stop layer has a third wet etch rate, and the first wet etch rate and the third wet etch rate are lower than the second wet etch rate.
